(19) United States
(12) Patent Application Publication
(10) Pub. No.: US 2021/0375710 A1
(43) Pub. Date: Dec. 2, 2021

(54) SEMICONDUCTOR ELEMENT INTERMEDIATE, AND METHOD OF PRODUCING SEMICONDUCTOR ELEMENT INTERMEDIATE

(71) Applicant: Mitsui Chemicals, Inc., Minato-ku, Tokyo (JP)

(72) Inventors: Hiroko WACHI, Chiba-shi, Chiba (JP); Hirofumi TANAKA, Tsukuba-shi, Ibaraki (JP); Yasuhisa KAYABA, Urayasu-shi, Chiba (JP); Kenichi FUJII, Yokohama-shi, Kanagawa (JP)

(73) Assignee: Mitsui Chemicals, Inc., Minato-ku, Tokyo (JP)

(21) Appl. No.: 17/284,488

(22) PCT Filed: Nov. 19, 2019
(86) PCT No.: PCT/JP2019/045323

§ 371 Date: Apr. 12, 2021

(30) Foreign Application Priority Data
Nov. 22, 2018 (JP) 2018-219498

(51) Int. Cl. H01L 23/31; H01L 23/29; H01L 21/02

(52) U.S. Cl. CPC H01L 23/3178; H01L 23/291; H01L 21/02205; H01L 21/0228; H01L 21/02175

(57) ABSTRACT

A method of producing a semiconductor element intermediate includes: a preparing step of preparing a substrate having a recessed part on a surface thereof; and a filling step of filling tin oxide into the recessed part by an atomic layer deposition method at a substrate temperature of 250° C. or higher, using a tin oxide precursor including a compound represented by the following Formula (1). In Formula (1), each of R¹ to R⁴ independently represents an alkyl group having from 1 to 6 carbon atoms.

### TECHNICAL FIELD

The present disclosure relates to a semiconductor element intermediate and a method of producing a semiconductor element intermediate.

### BACKGROUND ART

In recent years, as patterns of semiconductors have become fine, it is required to process a semiconductor at dimensions that are smaller than a convergent limit of the exposure used in lithography. As a method for fine processing of such a semiconductor pattern, for example, a multi-layer resist method has been proposed. The multi-layer resist method is a method of finely processing a body to be processed, in which a lower layer resist and an upper layer resist are provided on the body to be processed and a pattern is transferred sequentially from the upper layer to the lower layer by etching. A hydrolysis-condensation film, such as a SOG (spin-on-glass) film, TEOS (tetraethoxysilane) or the like, or a SiO₂ film such as a crosslinkable silsesquioxane film, are often used as a lower layer resist.

In response to needs for fine processing, a self-alignment method has been proposed, and for example, a method using a spacer has been proposed. The spacer is used as a mask for pattern formation of a lower layer. A spacer material is selected so as to have an appropriate etching selectivity. The spacer is removed by etching after the pattern formation of the lower layer is completed, thus the spacer will not remain on a manufactured final semiconductor device.

Examples of the method using a spacer include a method described in Japanese Patent Application Laid-Open (JP-A) No. 2018-6742. In Japanese Patent Application Laid-Open (JP-A) No. 2018-6742, a spacer (tin oxide) is provided on sidewalls of a protrusion part (consisting of silicon or carbon) formed on an underlying layer (silicon oxide or silicon nitride), and a pattern is formed on the underlying layer. By appropriately setting an etching selectivity between the protrusion part and the spacer, the protrusion part is removed first by etching, and the pattern of the underlying layer is finely formed by using the spacer as a mask for etching (FIG. 5 of Japanese Patent Application Laid-Open (JP-A) No. 2018-6742).

In the method of forming a spacer 109 in Japanese Patent Application Laid-Open (JP-A) No. 2018-6742, first, a spacer is uniformly deposited (conformally) along surface shapes of a underlying layer 103 and a protrusion part 101 (FIG. 2 of Japanese Patent Application Laid-Open (JP-A) No. 2018-6742). Then, the spacer is removed from the horizontal surface without being completely removed from sidewalls of the protrusion part 101 (FIG. 3 of Japanese Patent Application Laid-Open (JP-A) No. 2018-6742). In Japanese Patent Application Laid-Open (JP-A) No. 2018-6742, the underlying layer 103 becomes available for etching as a result of removal of the spacer material from the horizontal surface.

In a self-alignment method, by applying a technique of preventing positional error due to exposure (Self-Aligned Blocking, hereinafter, also referred to as “SAB”), cutting a part of a pattern is enabled and formation of a pattern having a fineness smaller than a convergent limit of the exposure can be achieved. SAB is a method in which a material having the etching resistance is filled into parts where cutting away of parts of a pattern is not desired, thereby avoiding cutting away of the non-target parts. This method is used for formation of vias and the like.

In SAB, first, a first pattern is formed using a first material. When the first pattern is the above-described spacer, an interval of patterns can be made smaller than a convergent limit of the exposure. After a second pattern is obtained by filling a second material into recessed parts that are formed by the first pattern, a mask having openings is formed thereon so as to cover the first pattern and the second pattern. Depending on the etching characteristics—for example, when a condition capable of easily etching the first pattern is adopted, etching performed in the above state will result in etching of only portions of the first pattern that are exposed at the openings of the mask while the second pattern provides protection from etching. Therefore, it is required to fill the second material into the recessed parts without any gap, in SAB.

When the mask having openings is formed on the first pattern without the filling of the second material, not only parts that are desired to be cut away but also the other parts of the first pattern are exposed at the openings, because the openings have a size that is at least the convergent limit of the exposure. Therefore, the non-target parts are also cut.

In general, SAB often takes the configuration in which a pattern of a lower layer resist provided on a substrate is regarded as a first pattern, and in which recessed parts formed by the first pattern are filled with a second material having different etching characteristics. Since a SiO₂ film such as a TEOS film, is often used as a lower layer resist, it is preferable to use, as the second material, a material having etching characteristics different from those of SiO₂, and examples of the material include tin oxide. Tin oxide has high etching resistance to CF₄ gas, while it has high etching rate to chlorine gas, as compared with those of a SiO₂ film, such as TEOS film. Therefore, by selecting the etching gas for use, a tin oxide film can be provided with etching resistance or can be removed well.

However, recessed parts in SAB have become finer because the fineness of patterns has increased as described above, and thus, it has become difficult to fill tin oxide into the fine recessed parts without any gap.

Here, examples of the method of filling recessed parts include a method described in Japanese Patent Application Laid-Open (JP-A) No. 2016-92051. Japanese Patent Application Laid-Open (JP-A) No. 2016-92051 describes a method of filling silicon used as electrodes in a recessed part such as a through hole or a contact hole. However, the method is not for filling tin oxide as an etching protective material as described in SAB.

In Japanese Patent Application Laid-Open (JP-A) No. 2016-92051, tin, which has a low melting point, is used together with silicon, which is a group IV semiconductor, so as to reduce the occurrence of cavities, such as seams and voids, when amorphous silicon is transferred to recessed parts by annealing. Since the melting point of tin is extremely low as compared with the melting point of silicon, the melting point of the material as a whole significantly decreases, thus enabling smooth transfer of amorphous silicon to the recessed parts by annealing. As a result, the occurrence of cavities is reduced when the recessed parts are filled.

International Publication (WO) No. 2019/50735 describes a method, as a fine processing method, in which metallic tin is filled into a recessed part using an atomic layer deposition method (ALD: Atomic Layer Deposition), a chemical vapor deposition method (CVD: chemical vapor deposition), or another method. The metallic tin is further transformed into tin oxide under an oxidation atmosphere at from room temperature to 800° C.

Japanese National-phase Publication (JP-A) No. 2005-519480 describes a method of reducing a gap size in a substrate having a submicron geometry. Specifically, a method is described which includes coating an organic polymer material or an organic metal material on a substrate surface, and on sidewalls and bottom walls of trenches or holes, by using CVD, plasma-enhanced chemical vapor deposition method (p-CVD), ALD, or the like.

Japanese National-phase Publication (JP-A) No. 2019-521518 describes a method of physically separating devices from each other, addressing the situation in which gaps and spaces between devices have been decreasing due to the continuous decrease in device sizes. Specifically, a method is described which includes forming a film on a surface of a substrate, a bottom face, and sidewalls extending along a depth from the surface to the bottom face in the substrate, and expanding the film.

The above-described film is a metallic film or metal-containing film that is formed by using CVD, p-CVD, ALD, or the like.

### SUMMARY OF INVENTION

### Technical Problem

As described above, in SAB, it is desired to fill tin oxide into the recessed parts without any gap. However, the gapless filling is difficult because the gap filling property decreases as the recessed parts become finer.

The technique in Japanese Patent Application Laid-Open (JP-A) No. 2018-6742 mentioned above is the technique of removing tin oxide from the bottom part of a recessed part and applying tin oxide only on the sidewalls of the first pattern, rather than a technique of filling the recessed part. Japanese Patent Application Laid-Open (JP-A) No. 2016-92051 is based on the premise of filling amorphous silicon. Furthermore, in Japanese Patent Application Laid-Open (JP-A) No. 2016-92051, the gap filling property is improved by the method, which incurs energy costs because the method needs to be performed under pressurizing and heating conditions in which the material melts.

The invention according to the present disclosure is made in consideration of the above circumstances. The invention according to the present disclosure aims to provide a semiconductor element intermediate having an excellent gap filling property of tin oxide into fine patterns and a method of producing a semiconductor element intermediate.

### Solution to Problem

Specific means for solving the above-described problem are as follows.

<1> A method of producing a semiconductor element intermediate, the method comprising:

a preparing step of preparing a substrate having a recessed part on a surface thereof; and

a filling step of filling tin oxide into the recessed part by an atomic layer deposition method at a substrate temperature of 250° C. or higher, using a tin oxide precursor including a compound represented by the following Formula (1):

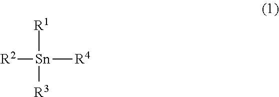

wherein each of R¹ to R⁴ in Formula (1) independently represents an alkyl group having from 1 to 6 carbon atoms.

<2> The method of producing a semiconductor element intermediate according to <1>, wherein a width of the recessed part is less than 50 nm.
<3> The method of producing a semiconductor element intermediate according to <1> or
<2>, wherein the tin oxide precursor has a molecular size of 0.7 nm or less.
<4> The method of producing a semiconductor element intermediate according to any one of <1> to <3>, wherein the tin oxide that has been filled into the recessed part in the filling step satisfies the following criteria (A), (B), and (C), when measured by X-ray photoelectron spectroscopy:

(A) a content of tin atoms is 30 atm % or more;

(B) a ratio of carbon atoms to tin atoms (atom ratio, C/Sn) is 0.4 or less; and

(C) a ratio of nitrogen atoms to tin atoms (atom ratio, N/Sn) is 0.03 or less.

<5> The method of producing a semiconductor element intermediate according to <4>, wherein the tin oxide that has been filled into the recessed part in the filling step further satisfies the following criterion (D), when measured by X-ray photoelectron spectroscopy:

(D) a ratio of oxygen atoms to tin atoms (atom ratio, O/Sn) is 1.5 or more.

<6> A semiconductor element intermediate, comprising:

a substrate having a recessed part with a width of less than 50 nm on a surface thereof; and

a tin oxide filler filled into the recessed part,

wherein the tin oxide filler satisfies the following criteria (A), (B), and (C), when measured by X-ray photoelectron spectroscopy:

(A) a content of tin atoms is 30 atm % or more;

(B) a ratio of carbon atoms to tin atoms (atom ratio, C/Sn) is 0.4 or less; and

(C) a ratio of nitrogen atoms to tin atoms (atom ratio, N/Sn) is 0.03 or less.

<7> The semiconductor element intermediate according to <6>, wherein the tin oxide filler further satisfies the following criterion (D), when measured by X-ray photoelectron spectroscopy:

(D) a ratio of oxygen atoms to tin atoms (atom ratio, O/Sn) is 1.5 or more.

### Advantageous Effects of Invention

According to the present disclosure, a semiconductor element intermediate having an excellent gap filling property of tin oxide into fine patterns and a method of producing a semiconductor element intermediate can be provided.

### BRIEF DESCRIPTION OF DRAWINGS

FIG. 1 is a graph showing a scanning electron micrograph (A) of a cross-sectional surface of the evaluation sample in Example 1.

FIG. 2 is a graph showing a scanning electron micrograph (B) of a cross-sectional surface of the evaluation sample in Example 1.

### DESCRIPTION OF EMBODIMENTS

Hereinafter, embodiments of the present disclosure will be described.

In the present disclosure, any numerical range expressed using “to” refers to a range that includes the numerical values indicated before and after “to” as the minimum value and maximum value.

Further, in the present disclosure, when plural substances corresponding to the same component exist in the composition, the amount of a component in a composition refers to a total amount of the plural substances corresponding to the component exist in the composition, unless otherwise specified.

In the present disclosure, the term “step” includes not only a separate step but also a step that is not clearly distinguished from other steps as long as an intended purpose of the step is achieved therefrom.

In the notation of a group (atomic group) in the present disclosure, the notation without an indication of substitution and unsubstitution encompasses those having no substituent group and those having a substituent group. For example, the term “alkyl group” encompasses not only an alkyl group having no substituent group (unsubstituted alkyl group) but also an alkyl group having a substituent group (substituted alkyl group).

Chemical structural formulae in the present disclosure may be described as simplified structural formulae in which hydrogen atoms are omitted.

<Method of Producing Semiconductor Element Intermediate>

The method of producing a semiconductor element intermediate according to the present disclosure includes: a preparing step of preparing a substrate having a recessed part on a surface thereof; and a filling step of filling tin oxide into the recessed part by an atomic layer deposition method at a substrate temperature of 250° C. or higher, using a tin oxide precursor including a compound represented by the following Formula (1).

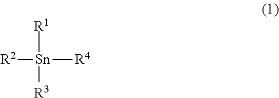

In Formula (1), R¹ to R⁴ each independently represent an alkyl group having from 1 to 6 carbon atoms.

Hereinafter, preferred aspects of each of the steps will be explained in detail.

<Preparing Step>

The method of producing a semiconductor element intermediate according to the present disclosure includes a preparing step of preparing a substrate having a recessed part on a surface thereof.

<Substrate>

The semiconductor element intermediate according to the present disclosure includes a substrate having a recessed part on a surface thereof. Examples of the substrate include a semiconductor substrate such as a silicon substrate, a glass substrate, a quartz substrate, a stainless substrate, and a plastic substrate. The silicon substrate may be a silicon substrate on which an interlayer insulation layer (Low-k film) or the like is formed.

The substrate is provided with a recessed part on its surface. The substrate having a recessed part on a surface thereof may be a substrate on which a recessed part is produced by the user, or may be a substrate having a recessed part on a surface thereof that can be obtained, for example by purchase. The method of producing a recessed part on a substrate is not particularly limited, and examples thereof include methods using sputtering or etching. From the viewpoint of forming a fine recessed part, the recessed part may be formed using a spacer. The method of forming a spacer is not particularly limited, and a commonly known method can be applied.

A material for forming a recessed part is not particularly limited as long as the material has etching characteristics different from those of tin oxide. Examples of the material having etching characteristics different from those of tin oxide include metallic oxides such as SiO₂, TiO₂, Al₂O₃, ZrO₂, HfO₂, and InO, nitrides such as TiN, TaN, and SiN, and metals such as Si.

A recessed part is formed on a surface on a substrate. The recessed part may be provided in any region as long as it is provided on the surface on the substrate. For example, the recessed part may be formed in at least one layer of a multi-layer resist layer, and is preferably formed in a lower layer resist. The recessed part may be formed in the substrate. The recessed part may be formed to extend over two or more layers, and for example, may be formed at a depth region of from the lower layer resist to the inside of the substrate.

The recessed part preferably includes a part with a width of less than 50 nm.

The semiconductor element intermediate according to the present disclosure has an excellent gap filling property of tin oxide in fine patterns, and thus, the gap filling property of tin oxide improves even when the width of the recessed part is less than 50 nm.

The width of the recessed part may be 30 nm or less, 20 nm or less, 15 nm or less, or 5 nm or less. The recessed part may include a part with a width of 50 nm or more.

In the present disclosure, the width of the recessed part means the width of a groove when the recessed part is a groove, and means the diameter of a surface opening when the recessed part is a hole.

The ratio of the depth of the recessed part to the width of the recessed part (depth/width, also referred to as an aspect ratio) is preferably from 0.5 to 30, and more preferably from 1 to 20.

The width of the recessed part and the depth of the recessed part are measured using an image at an observation magnification of 300,000 times obtained by using a scanning electron microscope (for example, S-5000 manufactured by Hitachi, Ltd.).

<Filling Step>

The method of producing a semiconductor element intermediate according to the present disclosure includes a filling step of filling tin oxide into the recessed part by an atomic layer deposition method at a substrate temperature of 250° C. or higher, using a tin oxide precursor including a compound represented by the above-described Formula (1).

The atomic layer deposition method (ALD: Atomic Layer Deposition) is a method in which a cycle of the following steps (1) to (4) is repeated.

(1) Supplying a precursor and the like that are gaseous raw materials

(2) Purging (that is, stopping the supply of the precursor)

(3) Treating with plasma, heat, or the like

(4) Purging Examples of the ALD include a plasma ALD and a thermal ALD, and it is preferable to use the plasma ALD.

The chemical vapor deposition method (CVD: Chemical Vapor Deposition) is a method in which supplying of a precursor and the like and treating with plasma, heat, or the like are simultaneously and continuously performed.

In the ALD, each of introducing (also referred to as pulsing) and discharging (also referred to as purging) is performed as an independent step. Thus, the reaction ends at a time when sites capable of adsorbing the precursor molecules are depleted on a surface of a target object. Therefore, it is possible to control film thickness and quality of materials at an atomic layer level, in the ALD.

An ALD apparatus is provided with a chamber. The chamber is provided with a gas inlet and a purging opening to purge gas.

The chamber preferably includes two or more gas inlets. For example, the chamber is preferably provided with a first pipe for supplying a precursor into the chamber, and a second pipe for supplying a carrier gas and an oxidation agent.

The tin oxide precursor may be stored in a container provided outside the chamber, and may be supplied together with the carrier gas into the chamber through the first pipe.

Furthermore, the ALD apparatus includes a component that is required for maintaining a desired pressure and temperature inside the chamber during deposition. In the case of a plasma ALD apparatus, an upper electrode and a lower electrode are provided inside the chamber, and plasma is thereby generated.

(1) Supplying Gaseous Raw Material

First, in the filling step, the substrate having a recessed part on a surface thereof is placed inside the chamber. Then, the gaseous raw material is supplied into the chamber. The gaseous raw material includes the tin oxide precursor and the oxidation agent, and may include other components. These are supplied into the chamber together with the carrier gas. In a preferred embodiment, the tin oxide precursor and the carrier gas are supplied together into the chamber, and the oxidation agent such as oxygen and the carrier gas are supplied together into the chamber through another pipe.

The tin oxide precursor includes a compound represented by the following Formula

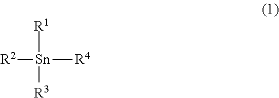

In Formula (1), R¹ to R⁴ each independently represent an alkyl group having from 1 to 6 carbon atoms.

Examples of the alkyl group having from 1 to 6 carbon atoms include a methyl group, an ethyl group, a propyl group, an isopropyl group, a butyl group, an isobutyl group, t-butyl group, a pentyl group, and a hexyl group. Among them, a methyl group is preferable.

The tin oxide precursor is preferably selected from the viewpoint of the molecular size. It is conceivable that a tin oxide precursor having a molecular size closer to the distance between oxygen atoms in O—Sn—O (i.e., 0.33 nm) enters more easily. The molecular size of the tin oxide precursor is preferably 0.7 nm or less, and more preferably 0.55 nm or less.

The molecular size is measured by using the molecular size measurement function of ChemOffice 2016 Chem3D 16.0 (manufactured by PerkinElmer, Inc.).

Examples of the tin oxide precursor include tetrakis(dimethylamino)tin (the molecular size: 0.76 nm), tetrachlorotin (the molecular size: 0.39 nm), and tetramethyltin (the molecular size: 0.53 nm). Among them, tetramethyltin is more preferable.

Tetramethyltin is preferable also from the viewpoint of removability of reaction byproducts.

The oxidation agent is not particularly limited as long as the oxidation agent is capable of oxidizing the tin oxide precursor. Examples of the oxidation agent include oxygen, ozone, water, and hydrogen peroxide. Among them, oxygen or water is preferable, and oxygen is more preferable. These may be used in combination.

Examples of the carrier gas include argon, helium, and nitrogen.

The tin oxide precursor is supplied into the chamber together with the carrier gas, in a gaseous state. In the case in which the tin oxide precursor is stored in a container provided outside the chamber, it is preferable to introduce the carrier gas into the container and to supply the tin oxide precursor into the chamber together with the carrier gas.

The flow rate of the carrier gas that is introduced into the container is preferably from 0.1 ml/min to 100 ml/min, more preferably from 1 ml/min to 30 ml/min, and still more preferably from 1.5 ml/min to 10 ml/min.

In the case in which the flow rate of the carrier gas that is introduced into the container is 100 ml/min or less, the clogging in the pipe tends to be suppressed, even when the reactivity of the tin oxide precursor is high or the boiling point is low. In the case in which the flow rate of the carrier gas that is introduced into the container is 0.1 ml/min or more, the reaction speed tends to be sufficiently maintained.

The flow rate of the oxidation agent is preferably from 1 ml/min to 3,000 ml/min, and more preferably from 1 ml/min to 30 ml/min. The oxidation agent is preferably supplied into the chamber together with the carrier gas. The flow rate of the carrier gas that is supplied together with the oxidation agent is preferably from 1 ml/min to 3,000 ml/min, and more preferably from 1 ml/min to 600 ml/min.

The length of time for which the tin oxide precursor is supplied is preferably set, as appropriate, based on the size of the substrate, and, for example, it may be from 0.5 seconds to 5 minutes.

The temperature of the substrate having a recessed part on a surface thereof is 250° C. or higher.

In the case in which the temperature of the substrate is at 250° C. or higher, the reaction rate of the gaseous raw material becomes high and the unreacted precursor component is reduced. As a result, the molecules of the produced tin oxide are densely arranged, and thus, tin oxide can be filled without any gap. From a viewpoint similar to that described above, the temperature of the substrate is preferably 270° C. or higher.

The upper limit of the temperature of the substrate is not particularly limited, and for example, it is preferably 500° C. or lower.

The temperature of the substrate is measured using a commercially available radiation thermometer (for example, infrared radiation thermometer with laser marker AD-5634, manufactured by A&D Co., Ltd.).

The temperature inside the chamber is preferably 500° C. or lower, more preferably from room temperature (for example, 20° C.) to 500° C., and still more preferably from 20° C. to 200° C.

In the case in which the temperature inside the chamber is 500° C. or lower, the stability of the gaseous raw material such as the tin oxide precursor tends to be ensured.

When the temperature inside the chamber is too high, it is conceivable that, depending on the kind of the tin oxide precursor, the tin oxide precursor preferentially reacts with minor components, such as O₂, H₂O, and N₂, from the atmosphere in the chamber, rather than reacting with the substrate surface. As a result, the tin oxide precursor attaches to the substrate after having grown into a particle having a size that is equal to or larger than the width of the recessed part, and, therefore, clogging at the upper part of the recessed part tends to occur. Further, in the case in which the temperature inside the chamber is too high, the tin oxide precursor may be thermally decomposed before reacting with the substrate surface, and a film may not be formed.

The pressure inside the chamber is preferably from 10 Pa to 1,000 Pa, and more preferably from 10 Pa to 100 Pa.

The inside of the chamber is depressurized so as to maintain the above-described pressure until the completion of the filling step of the ALD, through the steps of (1) supplying the gaseous raw material, (2) purging, (3) treating with plasma, heat, or the like, and (4) purging.

When the tin oxide precursor and the oxidation agent are supplied to the substrate having a recessed part on a surface thereof, a hydroxy group is adsorbed on the substrate surface including a recessed part, due to the presence of the oxidation agent. The hydroxy group reacts with the tin oxide precursor, and the tin oxide precursor is adsorbed on the substrate surface by chemical adsorption. Byproducts are generated by this reaction.

In the case in which tetramethyltin is used as the tin oxide precursor, for example, methane is generated as a byproduct.

(2) Purging

Supplying the tin oxide precursor into the chamber is stopped, but the oxidation agent and the carrier gas are continued to be supplied, thereby removing the unreacted tin oxide precursor and the byproducts.

Specifics of the flow rate of the oxidation agent and the flow rate of the carrier gas supplied together with the oxidation agent are the same as those during (1) supplying the gaseous raw material, and preferable ranges are also the same.

The purging time is not particularly limited as long as the unreacted materials and byproducts are sufficiently removed, and for example, it may be from 1 second to 1 minute.

(3) Treating with Plasma, Heat, or the Like

While supplying the oxidation agent and carrier gas, plasma treatment is performed in the case of the plasma ALD, and heat treatment is performed in the case of the thermal ALD. The oxidation reaction of the tin oxide precursor is promoted by the treatment.

(3-1) Plasma Treatment

In the plasma treatment, from the viewpoint of avoiding a situation in which discharge does not occur, or in which the oxidation reaction becomes non-uniform due to the occurrence of local discharge, it is preferable to appropriately set the pressure inside the chamber, the flow rate of the carrier gas, the flow rate of the oxidation agent gas, a distance (gap distance) between the substrate surface and the upper electrode when the substrate is placed between the upper electrode and the lower electrode, a high-frequency power, and the like. The specific conditions are as follows.

Specifics of the flow rate of the oxidation agent and the flow rate of the carrier gas are the same as those during (1) supplying the gaseous raw material, and preferable ranges are also the same.

The gap distance is preferably from 10 mm to 50 mm, and more preferably from 10 mm to 30 mm.

The high-frequency power is preferably from 20 W to 200 W, and more preferably from 50 W to 150 W.

The length of time for the plasma treatment is not particularly limited as long as the oxidation reaction is sufficiently promoted and performed until no unreacted materials are left. For example, the length of time for the plasma treatment may be from 1 second to 1 minute.

(3-2) Heat Treatment

When the thermal ALD is performed, the temperature of the substrate is preferably 300° C. or higher.

The temperature inside the chamber is preferably from 20° C. to 300° C. At this time, the temperature of the substrate is at or higher than the temperature inside the chamber; the temperature difference between the substrate and inside the chamber is preferably 10° C. or more, and a bigger temperature difference is more preferable.

The upper limit of the temperature difference between the substrate temperature and the temperature inside the chamber may be 350° C. or less, or may be 300° C. or less.

In the thermal ALD, with the temperature of the substrate surface being higher than the temperature inside the chamber, the tin oxide precursor comes in contact with the substrate surface and is adsorbed thereto by chemical adsorption, and a tin oxide precursor layer is thereby formed. Subsequently, the surface of the tin oxide precursor layer reacts with the oxidation agent in the atmosphere in the chamber, and a first tin oxide layer is thereby formed. The first tin oxide layer is provided with OH groups on its surface, due to the action of the oxidation agent. Atomic layers are deposited one by one by sequentially repeating the process in which OH groups of the first tin oxide layer contact with the tin oxide precursor to undergo a further reaction.

(4) Purging

Purging is performed to remove the byproducts that have been generated by the above-described (3) treating with Plasma, Heat, or the like. The specifics of the condition of purging are the same as those in the above-described (2) purging, and preferable ranges are also the same.

The first layer is deposited by performing the above-described steps (1) to (4). A cycle of steps (1) to (4) is regarded as one cycle and repeated. It is preferable that the repetition number is appropriately set based on, for example, the width of the recessed part and the aspect ratio (the ratio of the depth of the recessed part to the width of the recessed part: depth/width). For example, the repetition number can be about 150 cycles in a case in which the recessed part has a width of from about 10 nm to about 15 nm and an aspect ratio of from 1 to 10.

Tin oxide is filled into the recessed part through the preparing step and filling step. The filling of tin oxide into the recessed part can be confirmed by observation using a scanning electron microscope (SEM).

(5) Other Steps

When the substrate having a recessed part having a width of 50 nm or more on a surface thereof is used, filling of tin oxide into the recessed part having a width of 50 nm or more may be performed by the above-described ALD, but the filling is preferably performed by filling a tin-containing composition by a coating method from the viewpoint of simplification.

The coating method is not particularly limited, and a commonly used method can be used.

Examples of the commonly used method include a dipping method, a spraying method, a spin coating method, and a bar coating method. For example, in the case of forming a film with a nano-sized film thickness (from several nanometers to several hundred nanometers), it is preferable to use a spin coating method.

The tin-containing composition includes a tin-containing compound. The tin-containing compound is not particularly limited, and examples include a tin alkoxide compound [≡Sn(OR), R: alkyl group], a tin oxide compound [>Sn(═O)], and SnO₂ colloidal particles. When the width of the recessed part is as small as from 50 nm to 150 nm, it is preferable to use a tin oxide compound, and more preferable to use a butyltin oxide [C₄H₉Sn(═O)OH].

The tin-containing composition preferably includes a solvent, in addition to the tin-containing compound. Examples of the solvent include water, and a water-soluble solvent. The solvent may be used singly or in combination of two or more kinds thereof. As the water-soluble solvent, an alcohol solvent such as methanol, ethanol, 1-propanol, isopropanol, or butyl alcohol is preferable.

The content ratio of the tin-containing compound in the tin-containing composition is not particularly limited as long as the tin-containing composition has a property that enables coating. In the case of the width of the recessed part being as small as from 50 nm to 200 nm, it is preferable to adjust the content of the tin-containing compound. Specifically, the tin content in the filler filled into the recessed part is adjusted preferably to from 1 atm % or more to less than 30 atm %, and more preferably to from 2 atm % to 30 atm %.

When the composition includes a solvent, it is preferable to perform drying after the composition including the tin-containing compound is coated. The drying temperature is preferably set appropriately depending on the solvent to be used, and for example, the drying temperature may be from 80° C. to 300° C. The drying temperature refers to the surface temperature of the substrate to which the tin-containing composition has been applied. Drying can be performed by a commonly used method, and for example, can be performed by using a hot plate.

When an organic tin compound such as a tin alkoxide compound or a tin oxide compound is used, tin oxide is obtained by calcining. The calcining temperature may be, for example, from 200° C. to 800° C. The calcining temperature refers to the surface temperature of the substrate to which the tin-containing composition has been applied. Calcining can be performed by a commonly used method using a furnace, a hot plate, or the like.

When a substrate having a recessed part having a width of 50 nm or more in addition to a recessed part having a width of less than 50 nm on a surface thereof is provided, the ALD is applied to the filling of the recessed part having a width of less than 50 nm, and the coating method using the tin-containing composition is applied to the filling of the recessed part having a width of 50 nm or more, the order of performing the ALD and the coating method is not particularly limited, and either may be performed first. From the viewpoint of ensuring filling into the fine recessed part, it is preferable to perform filling by the ALD first, and then perform filling by the coating method.

<Tin Oxide Filler>

The semiconductor element intermediate obtained by the method of producing a semiconductor element intermediate according to the present disclosure includes tin oxide filled in the recessed part (i.e., a tin oxide filler filled in the recessed part).

The tin oxide filler includes a tin atom and an oxygen atom, and may further include other atoms. It is assumed that the other atoms are derived from a raw material such as the tin oxide precursor, or are inevitably mixed in from an apparatus or the like. Examples of the other atoms include a carbon atom, a nitrogen atom, a fluorine atom, a chlorine atom, and a silicon atom.

The content of tin atoms in the tin oxide filler is 30 atm % or more, preferably 31 atm % or more, more preferably 32 atm % or more, and still more preferably 33 atm % or more.

The upper limit of the content of tin atoms in the tin oxide filler is not particularly limited, and, for example, the upper limit may be 40 atm % or less or 34 atm % or less.

The content of oxygen atoms in the tin oxide filler is preferably 50 atm % or more, and more preferably 51 atm % or more.

The upper limit of the content of oxygen atoms in the tin oxide filler in not particularly limited, and for example, the upper limit may be 60 atm % or less or 66 atm % or less.

The C/Sn (atom ratio) in the tin oxide filler is preferably 0.4 or less, more preferably 0.37 or less, and still more preferably 0.

The O/Sn (atom ratio) in the tin oxide filler is preferably 1.5 or more, and more preferably 1.53 or more.

Tin oxide may be present in the form of SnO, SnO₃, Sn₃O₄, or the like, in addition to SnO₂, but the stable form is SnO₂. The theoretical value of the O/Sn is 2 in the case of SnO₂, and thus the upper limit value of the O/Sn (atom ratio) is 2.

The N/Sn (atom ratio) in the tin oxide filler is preferably 0.03 or less, more preferably 0.02 or less, still more preferably 0.01 or less, and particularly preferably 0.

From the viewpoint of suppressing pyrolysis of the tin oxide precursor, it is preferable to use, as the tin oxide precursor, a compound that does not include a nitrogen atom, in which case the N/Sn (atom ratio) is 0.

A smaller content of carbon atoms in the tin oxide filler is more preferable. For example, the content of carbon atoms in the tin oxide filler is preferably 15 atm % or less, more preferably 13 atm % or less, and still more preferably 0 atm %.

A smaller content of nitrogen atoms in the tin oxide filler is more preferable. For example, the content of nitrogen atoms in the tin oxide filler is preferably 0.9 atm % or less, and more preferably 0 atm %.

A smaller content of the other atoms in the tin oxide filler is more preferable. For example, the content of fluorine atoms in the tin oxide filler is preferably 2.0 atm % or less, and more preferably 1 atm % or less.

The content of silicon atoms in the tin oxide filler is preferably 10 atm % or less, and more preferably 5 atm % or less.

The content of chlorine atoms in the tin oxide filler is preferably 5.0 atm % or less, more preferably 1.0 atm % or less, and still more preferably 0 atm %.

Tin oxide filled in the recessed part (i.e., tin oxide filler filled in the recessed part) in the filling step preferably satisfies the following criteria (A), (B), and (C), when measured by X-ray photoelectron spectroscopy.

(A) The content of tin atoms is 30 atm % or more.

(B) The ratio of carbon atoms to tin atoms (atom ratio, C/Sn) is 0.4 or less.

(C) The ratio of nitrogen atoms to tin atoms (atom ratio, N/Sn) is 0.03 or less.

The gap filling property of tin oxide into the recessed part improves when the tin oxide filler satisfies the criteria (A) to (C). Although the reason therefor is not clear, it is conceivably as follows.

In the case in which the organic tin compound is used as the precursor for generating tin oxide, a substituent group of the tin oxide precursor includes a carbon atom, a nitrogen atom, and the like.

In the case in which the criteria (A) to (C) are not satisfied, the tin oxide precursor includes at least a certain amount of substituent groups that have not reacted with the oxidation agent. Because unreacted substituent groups are larger than an OH group that is generated as a result of the reaction, clogging at the upper part of the recessed part tends to occur. Furthermore, a film formation reaction does not occur at a part lower than the clogged upper part, as a result of which a void is formed.

In the case in which the criteria (A) to (C) are satisfied, the content of the other atoms other than tin atoms and oxygen atoms is low. In this case, it can be said that the efficiency of reaction from the tin oxide precursor to tin oxide is high. Therefore, it is conceivable that the gap filling property of tin oxide into the recessed part improves when the semiconductor element intermediate satisfies the criteria (A) to (C).

In this manner, tin oxide filled without any gap in the fine recessed part can be used not only as a spacer but also as an insulation material between electrodes and as a semiconductor element of a barrier film.

The components analysis by X-ray photoelectron spectroscopy (X-ray Photoelectron Spectroscopy, XPS method) can be performed by using a X-ray photoelectron spectrometer (for example, AXIS-NOVA (manufactured by Kratos Analytical Limited)). The measurement is performed by using, for example, monochromatic AlKα (1486.6 eV) as an X-ray source, and 700 μm×300 μm as an analysis region. The obtained spectrum is curve-fitted to perform peak separation between respective peaks. Subsequently, the area ratios among the respective peaks are measured, and the ratio of each atom at a surface of the tin oxide film is thereby measured.

Tin oxide that has been filled into the recessed part in the filling step (i.e., tin oxide filler filled in the recessed part) preferably further satisfies the following criterion (D), when measured by X-ray photoelectron spectroscopy.

(D) The ratio of oxygen atoms to tin atoms (atom ratio, O/Sn) is 1.5 or more.

The degassing amount when heated at 250° C. or higher can be reduced in the case in which the tin oxide filler further satisfies criterion (D) in addition to the criteria (A) to (C). Therefore, it is possible to further reduce heat shrinkability, further reduce the occurrence of a void, and further improve heat resistance.

<Semiconductor Element Intermediate>

The semiconductor element intermediate according to the present disclosure includes a substrate having a recessed part on a surface thereof, and a tin oxide filler filled in the recessed part.

In the semiconductor element intermediate according to the present disclosure, the same substrate as the substrate that is described in the method of producing a semiconductor element intermediate above can be used as the substrate having a recessed part on a surface thereof, and preferred aspects thereof are also the same.

In the semiconductor element intermediate according to the present disclosure, the same tin oxide filler as the tin oxide filler that is described in the method of producing a semiconductor element intermediate above can be used as the tin oxide filler that has been filled into the recessed part, and preferred aspects thereof are also the same.

Examples of the semiconductor element intermediate according to the present disclosure include an aspect in which specific examples and preferred aspects, described in the substrate and the tin oxide filler above, are appropriately combined.

Among them, the following aspect A is preferable as a semiconductor element intermediate according to the present disclosure.

<Aspect A>

The semiconductor element intermediate according to the aspect A includes a substrate having a recessed part with a width of less than 50 nm on a surface thereof, and a tin oxide filler filled into the recessed part, wherein the tin oxide filler satisfies the following criteria (A), (B), and (C), when measured by X-ray photoelectron spectroscopy.

(A) The content of tin atoms is 30 atm % or more.

(B) The ratio of carbon atoms to tin atoms (atom ratio, C/Sn) is 0.4 or less.

(C) The ratio of nitrogen atoms to tin atoms (atom ratio, N/Sn) is 0.03 or less.

In the semiconductor element intermediate according to the aspect A, the tin oxide filler preferably further satisfies the following criterion (D), when measured by X-ray photoelectron spectroscopy.

(D) The ratio of oxygen atoms to tin atoms (atom ratio, O/Sn) is 1.5 or more.

### EXAMPLES

The present disclosure will be specifically described below by way of Examples, but the present disclosure is not limited thereto.

### Example 1

“Silicon substrate a” to which a SiO₂ film had been provided by a heat chemical vapor deposition (heat CVD) was prepared.

As a plasma atomic layer deposition apparatus, an apparatus provided with plasma electrodes, supply lines for plural kinds of gas, a vacuuming line, a chamber, and a mechanism for controlling the substrate temperature was produced. The silicon substrate a was placed between an upper electrode and a lower electrode in the chamber. The gap distance between the upper electrode and the silicon substrate a was set to 20 mm. The pressure inside the chamber was reduced to 58.4 Pa, the temperature inside the chamber was set at 23° C., and the substrate temperature was set at 300° C.

Oxygen gas was introduced in the chamber together with argon gas at a flow rate of argon/oxygen of 210/10 [ml/min].

(1) Supplying Precursor

Tetramethyltin was injected into a container provided outside the chamber. Argon as a carrier gas was introduced into the container at a flow rate of 2 ml/min, and tetramethyltin was introduced into the chamber together with the carrier gas. The supply of tetramethyltin was stopped when the supply of tetramethyltin was performed for 3 seconds.

(2) Purging

After the supply of tetramethyltin was stopped, purging was performed by continuously flowing oxygen gas and argon gas for 30 seconds while vacuuming. At this time, the flow rate of argon/oxygen was maintained at 210/10 [ml/min].

(3) Plasma Treatment

Plasma treatment was performed for 1 second while continuously flowing oxygen gas and argon gas at the above-described flow rate. A high-frequency power in the plasma treatment was set to 100 W.

(4) Purging

After the plasma treatment, purging was performed for 10 seconds by continuously flowing oxygen gas and argon gas at the above-described flow rate while vacuuming.

A cycle of the above-described steps (1) to (4) was performed 150 times, so that a tin oxide film with a film thickness of 11.9 nm was produced on the silicon substrate a.

### Comparative Example 1

A tin oxide film with a thickness of 10 nm was formed on the silicon substrate a by the following plasma chemical vapor deposition method (plasma CVD) using tetramethyltin.

The silicon substrate a was placed between the upper electrode and the lower electrode in the chamber, in the same manner as in Example 1. The gap distance between the upper electrode and the silicon substrate a was set to 20 mm. The pressure inside the chamber was reduced to 58.4 Pa, the temperature inside the chamber was set at 23° C., and the substrate temperature was set at 100° C.

Oxygen gas was introduced into the chamber together with argon gas at a flow rate of argon/oxygen of 210/10 [ml/min]. Tetramethyltin was injected into the container provided outside the chamber. Argon as a carrier gas was introduced into the container at a flow rate of 2 ml/min, and tetramethyltin was introduced into the chamber together with the carrier gas. Subsequently, CVD treatment was performed for 30 seconds.

### Comparative Example 2

A tin oxide film with a thickness of 8.3 nm was formed on the silicon substrate a, in the same manner as in Example 1 except that the substrate temperature was changed from 300° C. to 100° C.

### Comparative Example 3

A tin oxide film with a thickness of 14.5 nm was formed on the silicon substrate a by making the following changes from Example 1.

(I) The tin oxide precursor was changed from tetramethyltin to tetrakis(dimethyl amino)tin [ Sn(N(CH₃)₂)₄].

(II) The substrate temperature was changed from 300° C. to 200° C.

(III) (1) In supplying the tin oxide precursor, the flow rate of argon as a carrier gas was changed from 2 ml/min to 10 ml/min.

(IV) (1) The supply time of the tin oxide precursor was changed from 3 seconds to 5 seconds.

(V) (2) The purging time was changed from 30 seconds to 10 seconds.

(VI) (4) The purging time was changed from 10 seconds to 3 seconds.

### Comparative Example 4

A tin oxide film with a thickness of 30 nm was formed on the silicon substrate a by the following coating method.

47.2 parts by mass of water was added to 0.08 parts by mass of polyvinyl alcohol (weight-average molecular weight (Mw)=22,000) (FUJIFILM Wako Pure Chemical Corporation), and the mixture was heated to 70° C. and dissolved by stirring for 1 hour. Furthermore, 46.7 parts by mass of a 15% by mass-SnO₂ colloidal dispersion (manufactured by Alfa Aeser) was added thereto, and the mixture was stirred for 1 hour and then allowed to stand for 23 hours, thereby obtaining a 7% by mass-SnO₂ colloidal aqueous solution.

The silicon substrate a was placed on a spin coater, and the SnO₂ colloidal aqueous solution was added dropwise thereto. Then, the substrate was rotated at 2000 rpm (the number of rotations per minute) for 60 seconds followed by drying at 100° C. for 1 minute. Subsequently, the substrate was calcined at 400° C. for 10 minutes under a nitrogen atmosphere (100 kPa).

TABLE 1

| | | | | | Amount | | | | | | | |
|---|---|---|---|---|---|---|---|---|---|---|---|---|
| | | | | | of gas | | | | | ALD | | |
| | | | | | supply | | Plasma | | | cycle | | |
| | | | | | | Flow | condition | | | Supply/ | | |
| | Film | Substrate | Pressure | | Flow | rate of | High- | | | Purge/ | | Film |
| | forma- | temper- | inside | Tin | rate of | Ar + | frequency | | CVD | Plasma/ | The | thick- |
| | tion | ature | chamber | oxide | Ar/O₂ | precursor | power | Gap | treatment | Purge | number of | ness |
| | method | [° C.] | [Pa] | precursor | [ml/min] | [ml/min] | [W] | [mm] | [s] | [s] | cycles | [nm] |
| Example 1 | ALD | 300 | 58.4 | SnMe₄ | 210/10 | 2 | 100 | 20 | — | 3/30/1/10 | 150 | 11.9 |
| Comparative | CVD | 100 | 58.4 | SnMe₄ | 210/10 | 2 | 100 | 20 | 30 | — | — | 10 |
| Example 1 | | | | | | | | | | | | |
| Comparative | ALD | 100 | 58.4 | SnMe₄ | 210/10 | 2 | 100 | 20 | — | 3/30/1/10 | 150 | 8.3 |
| Example 2 | | | | | | | | | | | | |
| Comparative | ALD | 200 | 58.4 | Sn(NMe₂)₄ | 210/10 | 10 | 100 | 20 | — | 5/10/1/3 | 150 | 14.5 |
| Example 3 | | | | | | | | | | | | |

<Components Analysis>

Components analysis was performed by X-ray photoelectron spectroscopy analysis method for each of the tin oxide films prepared in Example 1, and Comparative Examples 1 to 4. Specifically, each measurement was performed using AXIS-NOVA (manufactured by Kratos Analytical Limited) as an apparatus, monochromatic AlKα (1486.6 eV) as an X-ray source, and 700 μm×300 μm as an analysis region. The results are shown in Table 2.

TABLE 2

| | Components analysis result (atm %) | | | | | | | Atom ratio | | | |
|---|---|---|---|---|---|---|---|---|---|---|---|
| | C | O | Sn | F | N | Si | Cl | C/Sn | O/Sn | Sn/Sn | N/Sn |
| Example 1 | 12.0 | 51.6 | 33.2 | 0.3 | — | 2.9 | — | 0.36 | 1.55 | 1.00 | 0.00 |
| Comparative | 28.2 | 35.7 | 31.0 | 4.8 | — | — | 0.3 | 0.91 | 1.15 | 1.00 | 0.00 |
| Example 1 | | | | | | | | | | | |
| Comparative | 12.9 | 49.6 | 30.2 | 1.7 | — | 5.6 | — | 0.43 | 1.64 | 1.00 | 0.00 |
| Example 2 | | | | | | | | | | | |
| Comparative | 8.4 | 54.1 | 30.9 | 1.9 | 1.1 | 3.4 | 0.2 | 0.27 | 1.75 | 1.00 | 0.04 |
| Example 3 | | | | | | | | | | | |
| Comparative | 9.5 | 55.3 | 27.6 | — | 0.4 | 2.9 | — | 0.34 | 2.00 | 1.00 | 0.01 |
| Example 4 | | | | | | | | | | | |

In Table 2, “-” means that the indicated element was not detected.

<Evaluation of Recessed Part Gap Filling Property>

Evaluation samples were prepared in the same manner as those in the film formation in the above-described <Components Analysis> except that the silicon substrate a was changed to a silicon substrate b that is a substrate provided with a recessed part (width of 20 nm) on the silicon substrate a, and recessed part gap filling property was evaluated.

The silicon substrate b is a substrate obtained by providing a recessed part with a width of 20 nm and a depth of 100 nm by etching on a SiO₂ film on a surface of the silicon substrate a.

The gap filling property was evaluated by observing a cross-sectional surface of each evaluation sample by using a scanning electron microscope (S-5000 manufactured by Hitachi, Ltd., observation magnification of 300,000 times).

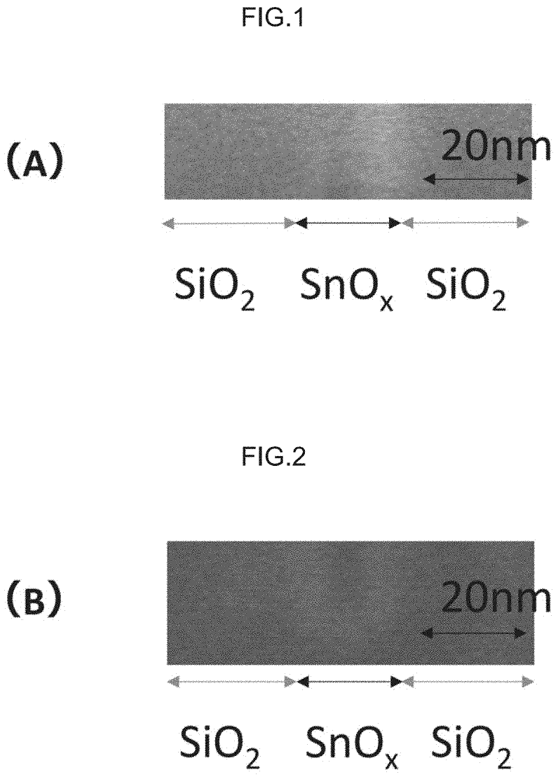

In FIG. 1, a scanning electron micrograph (A) of a cross-sectional surface of the evaluation sample in Example 1 is shown. The scanning electron micrograph (A) is a scanning electron micrograph of a cross-sectional surface at a depth of 20 nm from a surface.

In FIG. 2, a scanning electron micrograph (B) of a cross-sectional surface of the evaluation sample in Example 1 is shown. The scanning electron micrograph (B) is a scanning electron micrograph of a cross-sectional surface at a depth of 80 nm from a surface.

In Example 1, tin oxide was uniformly filled into the recessed part and no voids were observed.

In Comparative Examples 1 to 4, an upper part of the recessed part was clogged with tin oxide, and voids were formed at a lower part. Therefore, the recessed part was not sufficiently filled.

### DISCUSSION

In Comparative Example 1, plasma CVD was used and the criterion (B) (C/Sn: 0.4 or less) was not satisfied, and thus a decreased gap filling property was obtained. As a result, it is revealed that the recessed part cannot be sufficiently filled.

In Comparative Example 2, the substrate temperature was 100° C. and the criterion (B) (C/Sn: 0.4 or less) was not satisfied, and thus a decreased gap filling property was obtained. From the result of Comparative Example 2, it is revealed that the gap filling property decreases when the criterion (B) is not satisfied even if the criteria (A) and (C) are satisfied.

In Comparative Example 3, the tin oxide precursor was (dimethylamino)tin and the criterion (C) was not satisfied, and thus a decreased gap filling property was obtained. From the result of Comparative Example 3, it is revealed that the gap filling property decreases when the criterion (C) is not satisfied even when the criteria (A) and (B) are satisfied.

In Comparative Example 4, the coating method was used and the criterion (A) was not satisfied, and thus a decreased gap filling property was obtained. It is required to adjust the viscosity and the like in order to infiltrate the liquid into the fine recessed part in the coating method. Therefore, it is difficult for the coating method to satisfy the criterion (A). As a result, it is revealed that the recessed part cannot be sufficiently filled.

In contrast to Comparative Examples, in Example 1 where the criteria (A) to (C) were satisfied, tin oxide was uniformly filled in the recessed part having the width of as small as 20 nm and no voids were observed.

Furthermore, it is revealed that it is preferable to use ALD and to set the substrate temperature to 250° C. or higher in ALD from the comparison of Examples and Comparative Examples.

The disclosure of Japanese Application 2018-219498 filed on Nov. 22, 2018 is incorporated herein by reference in their entirety.

All publications, patent applications, and technical standards mentioned in this specification are incorporated herein by reference to the same extent as if each individual publication, patent application, or technical standard was specifically and individually indicated to be incorporated by reference.

1. A method of producing a semiconductor element intermediate, the method comprising:
a preparing step of preparing a substrate having a recessed part on a surface thereof; and
a filling step of filling tin oxide into the recessed part by an atomic layer deposition method at a substrate temperature of 250° C. or higher, using a tin oxide precursor including a compound represented by the following Formula (1): 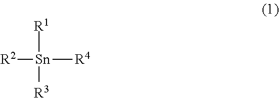
wherein each of R¹ to R⁴ in Formula (1) independently represents an alkyl group having from 1 to 6 carbon atoms.

2. The method of producing a semiconductor element intermediate according to claim 1, wherein a width of the recessed part is less than 50 nm.

3. The method of producing a semiconductor element intermediate according to claim 1, wherein the tin oxide precursor has a molecular size of 0.7 nm or less.

4. The method of producing a semiconductor element intermediate according to claim 1, wherein the tin oxide that has been filled into the recessed part in the filling step satisfies the following criteria (A), (B), and (C), when measured by X-ray photoelectron spectroscopy:
(A) a content of tin atoms is 30 atm % or more;
(B) a ratio of carbon atoms to tin atoms (atom ratio, C/Sn) is 0.4 or less; and
(C) a ratio of nitrogen atoms to tin atoms (atom ratio, N/Sn) is 0.03 or less.

5. The method of producing a semiconductor element intermediate according to claim 4, wherein the tin oxide that has been filled into the recessed part in the filling step further satisfies the following criterion (D), when measured by X-ray photoelectron spectroscopy:
(D) a ratio of oxygen atoms to tin atoms (atom ratio, O/Sn) is 1.5 or more.

6. A semiconductor element intermediate, comprising:
a substrate having a recessed part with a width of less than 50 nm on a surface thereof; and
a tin oxide filler filled into the recessed part,
wherein the tin oxide filler satisfies the following criteria (A), (B), and (C), when measured by X-ray photoelectron spectroscopy:
(A) a content of tin atoms is 30 atm % or more;
(B) a ratio of carbon atoms to tin atoms (atom ratio, C/Sn) is 0.4 or less; and
(C) a ratio of nitrogen atoms to tin atoms (atom ratio, N/Sn) is 0.03 or less.

7. The semiconductor element intermediate according to claim 6, wherein the tin oxide filler further satisfies the following criterion (D), when measured by X-ray photoelectron spectroscopy:
(D) a ratio of oxygen atoms to tin atoms (atom ratio, O/Sn) is 1.5 or more.
